(19) United States
(12) Patent Application Publication
(10) Pub. No.: US 2022/0301896 A1
(43) Pub. Date: Sep. 22, 2022

(54) SUBSTRATE PROCESSING APPARATUS AND SUBSTRATE PROCESSING METHOD

(71) Applicant: Kioxia Corporation, Tokyo (JP)

(72) Inventors: Yoshinori TOKUDA, Ota Tokyo (JP); Toshiaki YANASE, Yokohama Kanagawa (JP); Shinji MORI, Nagoya Aichi (JP)

(73) Assignee: Kioxia Corporation, Tokyo (JP)

(21) Appl. No.: 17/407,641

(22) Filed: Aug. 20, 2021

(30) Foreign Application Priority Data
Mar. 17, 2021 (JP) 2021-043715

(51) Int. Cl. H01L 21/67; H01L 21/3213

(52) U.S. Cl. CPC H01L 21/67069; H01L 21/32135

(57) ABSTRACT

A substrate processing apparatus includes a chamber, a supply pipe, a discharge pipe, a trap section, a heater, a buffer section, and a cooling pipe. The chamber houses a substrate. The supply pipe supplies a processing gas into the chamber. The discharge pipe discharges a gas produced in the chamber. The trap section is disposed in the discharge pipe. The heater heats the trap section. The buffer section is disposed downstream of the trap section in the discharge pipe. The cooling pipe cools the buffer section.

### CROSS-REFERENCE TO RELATED APPLICATION(S)

This application is based upon and claims the benefit of priority from Japanese Patent Application No. 2021-043715, filed Mar. 17, 2021, the entire contents of which are incorporated herein by reference.

### FIELD

Embodiments described herein relate generally to a substrate processing apparatus and a substrate processing method.

### BACKGROUND

For example, in manufacturing semiconductor storage devices, nickel maybe added to a substrate as catalyst in order to accelerate crystallization of a silicon layer formed on the substrate. The nickel remains on the substrate at the time the crystallization is completed. The remaining nickel partially reduces breakdown voltage, which can cause leakage current. In view of this, after the crystallization is performed as described above, an annealing treatment is conducted to remove the nickel from the substrate.

### DESCRIPTION OF THE DRAWINGS

FIGS. 1A to 1D are diagrams illustrating crystallization using nickel.

FIG. 2 schematically shows a configuration of a substrate processing apparatus according to at least one embodiment of the present disclosure.

FIG. 3 is a sectional view showing a structure of a supply pipe provided in the substrate processing apparatus.

FIG. 4 is a sectional view showing a structure of a cleaning pipe provided in the substrate processing apparatus.

FIG. 5 schematically shows a configuration of the substrate processing apparatus according to at least one embodiment of the present disclosure.

### DETAILED DESCRIPTION

In general, according to at least one embodiment, a substrate processing apparatus includes a chamber, a supply pipe, a discharge pipe, a trap section, a heating unit (heater), a buffer section, and a cooling unit (cooler). The chamber is configured to house a substrate. The supply pipe is configured to supply a processing gas into the chamber. The discharge pipe is configured to discharge a gas produced in the chamber. The trap section is disposed in the discharge pipe. The heating unit is configured to heat the trap section so that a first temperature of the trap section is higher than a process temperature of the substrate and is 300° C. or higher. The buffer section is disposed downstream of the trap section in the discharge pipe. The cooling unit is configured to cool the buffer section so that a second temperature at a downstream end part of the buffer section is lower than the first temperature.

Hereinafter, embodiments of the present disclosure will be described with reference to the attached drawings. In order to facilitate understanding of explanation, the same elements in the drawings are given the same reference signs, if applicable, and overlapping descriptions will be omitted.

A substrate processing apparatus 10 according to at least one embodiment of the disclosure is used in a process of removing nickel from a substrate 100 in a manufacturing process of a semiconductor storage device, such as a NAND flash memory. The substrate 100 is, for example, a silicon wafer. Prior to description of the substrate processing apparatus 10, the reasons for performing the above-described process will be described first.

The manufacturing process of a semiconductor storage device includes partially forming an amorphous silicon layer on the substrate 100 and then crystallizing this layer into a polysilicon layer. The polysilicon layer that is thus formed can be used as, for example, a channel of a memory cell transistor of a semiconductor storage device.

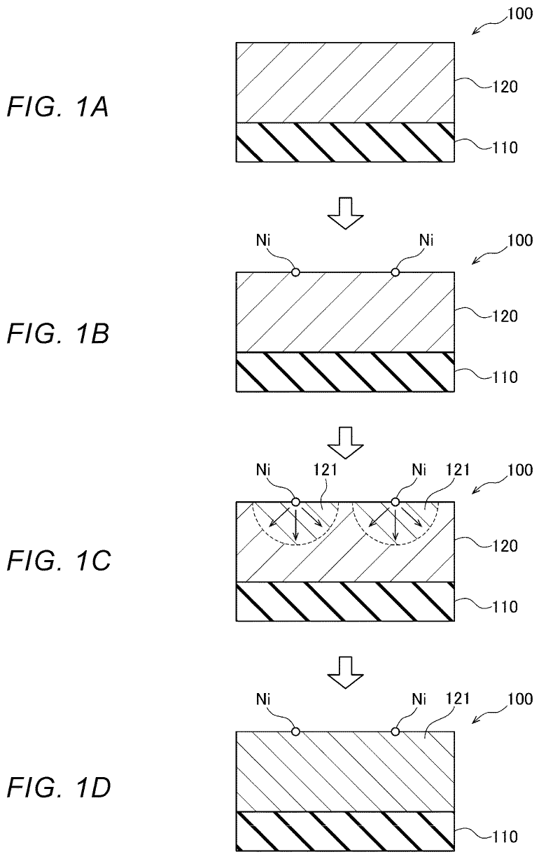

A method of forming a polysilicon layer will be described with reference to FIGS. 1A to 1D. FIGS. 1A to 1D are diagrams illustrating crystallization using nickel. First, as shown in FIG. 1A, an amorphous silicon layer 120 is formed so as to cover an insulating film 110, such as of a silicon oxide, formed on a substrate 100 (the entirety is not shown). The amorphous silicon layer 120 is formed by CVD, for example.

Next, as shown in FIG. 1B, nickel (Ni) is added to the surface of the amorphous silicon layer 120. The nickel functions as catalyst that facilitates crystallization of the amorphous silicon layer 120. The nickel is added by, for example, subjecting the substrate 100 to a gas containing nickel so that nickel will be absorbed in the surface of the amorphous silicon layer 120. Alternatively, the nickel may be added by applying a solution containing nickel to the surface of the amorphous silicon layer 120.

After nickel is added to the surface of the amorphous silicon layer 120, the substrate 100 is heated. The substrate 100 is heated in an atmosphere containing, for example, inert gas or hydrogen. The substrate 100 is heated at a temperature of, for example, 500 to 700° C. for approximately 4 to 8 hours. At this time, as shown in FIG. 1C, the added nickel functions as catalyst, whereby the amorphous silicon layer 120 is partially crystallized, while the grain sizes of the crystals are enlarged. Thus, the amorphous silicon layer 120 is partially converted into a polysilicon layer 121.

The area where the amorphous silicon layer 120 is converted into the polysilicon layer 121 increases as time elapses. After the substrate 100 is sufficiently heated, as shown in FIG. 1D, the area where the amorphous silicon layer 120 exists is almost or entirely converted into the polysilicon layer 121. The area where the amorphous silicon layer 120 has been converted into the polysilicon layer 121 has a lowered electric resistance and thus is able to sufficiently function as a channel of a memory cell transistor, or the like.

At the time the crystallization is completed, as shown in FIG. 1D, the nickel that is added as catalyst remains on the surface of the polysilicon layer 121. In addition, some amount of nickel may remain in a state of being diffused in the polysilicon and other parts. When a subsequent manufacturing process is performed in the state where nickel remains in the substrate 100, breakdown voltage is lowered at apart of the substrate 100, which may cause unexpected leakage current. In view of this, after the crystallization as shown in FIGS. 1A to 1D is performed, an annealing treatment is conducted to remove the nickel from the substrate 100 by using the substrate processing apparatus 10.

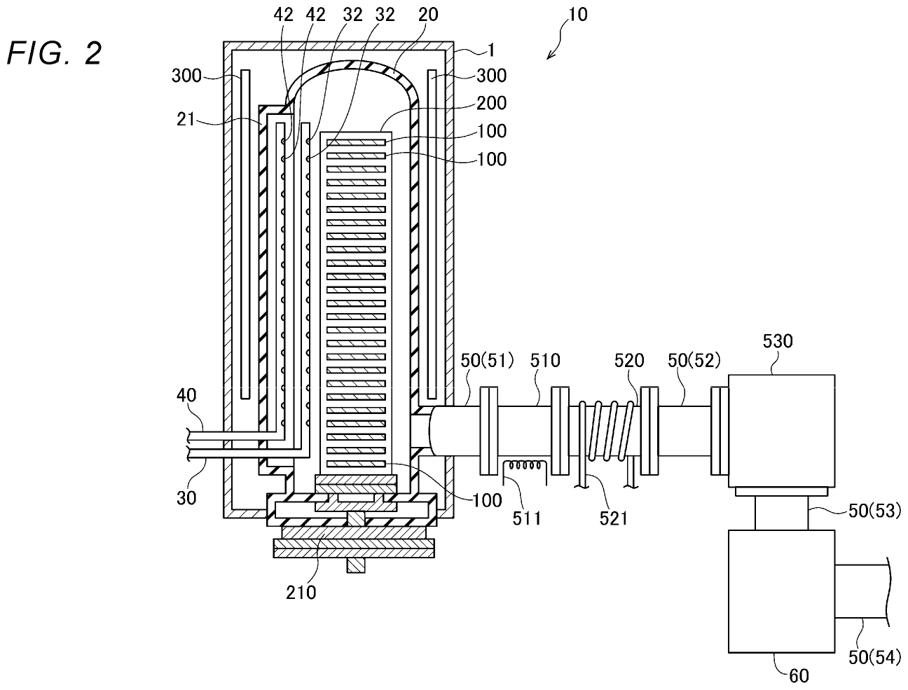

FIG. 2 schematically shows a configuration of the substrate processing apparatus 10 according to this embodiment. The configuration of the substrate processing apparatus 10 will be described with reference mainly to FIG. 2. As schematically shown in the drawing, the substrate processing apparatus 10 includes a chamber 20, a holder 200, heaters 300, a supply pipe 30, a discharge pipe 50, and a pump 60.

The chamber 20 is a container for housing the substrate 100. The chamber 20 may be formed into an approximately cylindrical shape and is entirely formed of a nickel-free material, for example, quartz. A lower end of the chamber 20 is supported in conjunction with the holder 200 (described later) by a base 210.

The chamber 20 includes a protrusion part 21 that is formed by protruding a part of a side surface of the chamber 20. The protrusion part 21 extends along a vertical direction and houses the cleaning pipe 40 (described later). The chamber 20, including the protrusion part 21, are entirely contained within an outer wall 1.

The holder 200 is configured to hold multiple substrates 100 to be treated, in the chamber 20. The holder 200 is also called a “boat” and has multiple projections (not shown) for holding outer circumferences of the substrates 100 from lower sides. The substrates 100 are respectively supported by the projections, so as to be mutually spaced along the vertical direction. These substrates 100 have already been subjected to the crystallization process, which is described with reference to FIGS. 1A to 1D. That is, each of the substrates 100 that are held by the holder 200 contains nickel. It is noted that the number of the substrates 100 that is actually held by the holder 200 may be greater than the number of the substrates 100 shown in FIG. 2.

The heaters 300 are configured to heat the substrate 100 from the outside of the chamber 20 and are, for example, electric heaters. Multiple heaters 300 surround the chamber 20 in a space between the chamber 20 and the outer wall 1. A heat insulating material (not shown) may be disposed between the heater 300 and the outer wall 1.

The supply pipe 30 is configured to supply a gas that contains carbon monoxide (CO), into the chamber 20. This gas is also called a “processing gas”, hereinafter. The processing gas may be a gas that contains only carbon monoxide or may be a gas that contains other components in addition to carbon monoxide. As described later, in response to supply of the processing gas from the supply pipe 30, the nickel that is contained in the substrate 100 reacts with carbon monoxide to produce nickel carbonyl and is thereby removed from the substrate 100.

The supply pipe 30 enters the chamber 20 from a lower part of the side surface of the chamber 20 and extends upward in the chamber 20. The side surface facing the holder 200 of the supply pipe 30 is formed with multiple introducing ports 32. The introducing ports 32 are openings that serve as outlets of the processing gas having passed through the supply pipe 30. The multiple introducing ports 32 are mutually spaced in the vertical direction or are formed with intervals that are adjusted so that the flow of gas in the chamber 20 will be uniform.

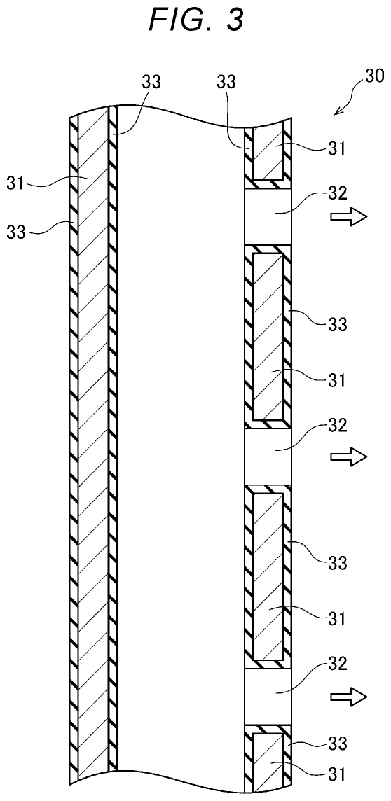

FIG. 3 shows a cross section obtained by cutting a part inside the chamber 20 of the supply pipe 30, at a plane passing a center axis along the longitudinal direction thereof. As shown in the drawing, the supply pipe 30 includes a base material 31 and a coating layer 33. The base material 31 is a body part of the supply pipe 30 and is formed of a metal material, such as stainless steel.

The coating layer 33 covers the whole surface of the base material 31. The coating layer 33 is formed of a nickel-free material. Examples of such a material include SiO₂, SiC, Al, Al₂O₃, nylon, and glass. The coating layer 33 covers an outer surface and an inner surface of the base material 31 and the entire inner surface of the introducing port 32. The reason for forming the coating layer 33 on the surfaces of the supply pipe 30 will be described later.

The description is continued by returning to FIG. 2. The discharge pipe 50 is configured to discharge gas that is produced in the chamber 20, from the chamber 20 to the outside. This gas is produced by reaction between the nickel contained in the substrate 100 and the carbon monoxide contained in the processing gas. The gas that is discharged from the chamber 20 through the discharge pipe 50 is also called a “produced gas”, hereinafter. The nickel that is contained in the substrate 100 is removed from the substrate 100 and is then discharged from the chamber 20 as the produced gas.

The pump 60 is disposed in the middle of the discharge pipe 50 and is configured to send the produced gas in a direction from the chamber 20 to the outside. The pump 60 includes a dry pump, for example.

As shown in FIG. 2, a trap section 510, a buffer section 520, and a valve 530 are provided in the middle of the discharge pipe 50. Each of these elements is formed with an inner flow passage (not shown), through which the produced gas and decomposition gas of the produced gas pass, and they constitute a part of the discharge pipe 50.

The discharge pipe 50 includes pipes 51 to 54. The pipe 51 is a tubular part that protrudes from a side surface of the chamber 20. The pipe 51 is made of, for example, quartz, and is integrally formed with the chamber 20, as one body. The pipe 51 is coupled to the trap section 510 at an end via a flange.

An end on a side opposite to the pipe 51 of the trap section 510 is coupled to the buffer section 520 via a flange. An end on a side opposite to the trap section 510 of the buffer section 520 is coupled to the pipe 52 via a flange. An end on a side opposite to the buffer section 520 of the pipe 52 is coupled to the valve 530 via a flange. The valve 530 and an intake port of the pump 60 are coupled by the pipe 53. The pipe 54 is coupled to a discharge port of the pump 60. The produced gas and other substances sequentially pass through the pipe 51, the trap section 510, the buffer section 520, the pipe 52, the valve 530, the pipe 53, the pump 60, and the pipe 54, in this order, to be discharged from the chamber 20 to the outside.

The trap section 510 is provided in the middle of the discharge pipe 50, as described above. A heater 511 is provided in the trap section 510. The heater 511 is, for example, an electric heater, and functions as a “heating unit” for raising the temperature of the trap section 510. The trap section 510 is heated by the heater 511, so that the whole trap section 510, including an inner surface to be brought into contact with the produced gas, will have a predetermined first temperature or higher. The “first temperature” is higher than the temperature of the substrate 100 when the process is performed in the chamber 20, and it is preferably set to 300° C. or higher. In at least one embodiment, the heater 511 heats the trap section 510 so that the temperature of the trap section 510 will be 500° C.

The buffer section 520 is provided downstream of the trap section 510 in the discharge pipe 50, as described above. A cooling pipe 521 is provided in the buffer section 520. The cooling pipe 521 cools the buffer section 520 by allowing a low-temperature coolant to pass through the cooling pipe 521, and the cooling pipe 521 functions as a “cooling unit” for lowering the temperature of the buffer section 520. The buffer section 520 is cooled by the cooling pipe 521, so that the temperature at its downstream end part will be a predetermined second temperature or lower. The “second temperature” is lower than the first temperature and is preferably set to 75° C. or lower, for example.

The valve 530 is provided between the buffer section 520 and the pump 60, as described above. The valve 530 is a pressure regulating valve configured to regulate the conductance of the discharge pipe 50 so as to maintain the pressure in the chamber 20 at a predetermined value.

A method of processing the substrate 100 by the substrate processing apparatus 10, that is, a specific method of removing the nickel from the substrate 100 will be described.

First, multiple substrates 100 that contain nickel are placed in the chamber 20 in the state of being held by the holder 200. The substrate processing apparatus 10 performs batch processing to process the multiple substrates 100 in the chamber 20 simultaneously.

After the substrates 100 are placed in the chamber 20, each of the substrates 100 starts to be heated by the heater 300. This heating is performed so that the temperature of the substrate 100 will be a predetermined target temperature or higher. The target temperature is set to, for example, 250° C. At this time, heating of the trap section 510 by the heater 511 and cooling of the buffer section 520 by the cooling pipe 521 are also started.

The processing gas is supplied from each of the introducing ports 32 of the supply pipe 30 into the chamber 20 at around the time the temperature of each of the substrates 100 reaches the target temperature. The carbon monoxide that is contained in the processing gas reaches each of the substrates 100. In response to this, the nickel (Ni), which is contained in the substrate 100, and the carbon monoxide (CO) cause a reaction represented by the following formula (1), to yield nickel carbonyl (Ni(CO)₄).

Ni+4CO→Ni(CO)₄ (1)

After coming off from the substrate 100, nickel carbonyl, which is a highly-volatile substance, becomes a produced gas and is discharged from the chamber 20 to the discharge pipe 50. As a result, the nickel is removed from the substrate 100.

The reaction of the formula (1) tends to occur when the temperature of the substrate 100 is 75° C. or higher. In this embodiment, the target temperature of the substrate 100 is set to 250° C., as described above, and therefore, the above-described reaction reliably occurs in every substrate 100. The target temperature of the substrate 100 may be any temperature that causes at least the reaction of the formula (1) and may be set to a temperature other than 250° C.

In heating the substrate 100 by the heater 300, the supply pipe 30 is also heated to a temperature of 75° C. or higher, at the same time. For this reason, in a case of forming the supply pipe 30 by using a material containing nickel, such as stainless steel, the reaction of the formula (1) occurs also on the surface of the supply pipe 30, and the produced nickel carbonyl can reach the substrate 100. As a result, the nickel carbonyl adheres to the substrate 100 to be decomposed, and the resultant nickel contaminates the substrate 100.

In view of this, in the substrate processing apparatus 10 according to at least one embodiment, the surface of the supply pipe 30 is covered with a coating layer 33 that is made of a nickel-free material. With this structure, the reaction of the formula (1) does not occur on the surface of the supply pipe 30, whereby the phenomenon of adhesion of the nickel carbonyl to the substrate 100 is prevented.

The area that is covered with the coating layer 33 of the supply pipe 30 maybe the entire surface of the supply pipe 30 or may be only a part of the surface of the supply pipe 30. The “part of the surface of the supply pipe 30” is, for example, a part to be heated to 75° C. or higher and to be brought into contact with carbon monoxide of the supply pipe 30. Thus, for example, the part outside the outer wall 1 of the supply pipe 30 may not be covered with the coating layer 33.

The base material 31 of the supply pipe 30 may be formed of a nickel-free material. Examples of such a material include SiO₂, SiC, Al, Al₂O₃, nylon, and glass. In this case, it is not necessary to form the coating layer 33, as shown in FIG. 3. In this manner, the supply pipe 30 may be, not partially, but entirely, formed of a nickel-free material.

The produced gas, which contains the nickel carbonyl generated through the reaction of the formula (1), flows into the discharge pipe 50 and reaches the trap section 510. As described above, the trap section 510 has been heated by the heater 511, to a temperature of the first temperature or higher. In at least one embodiment, the trap section 510 is heated to 500° C. Upon passing through the trap section 510, the produced gas causes a reaction represented by the following formula (2), whereby the nickel carbonyl (Ni(CO)₄) is decomposed into nickel (Ni) and carbon monoxide (CO).

Ni(CO)₄→Ni+4CO (2)

The nickel that is generated in accordance with the formula (2) is separated in the solid state and adheres to be deposited on the inner surface of the trap section 510. Thus, the trap section 510 is subjected to regular maintenance, for example, it is detached, and the nickel is removed.

In order to increase the area to be brought into contact with the produced gas, the trap section 510 preferably contains a plate member (not shown). This structure enables accelerating the reaction of the formula (2). In addition, the storable amount of the nickel in the trap section 510 can be increased.

The reaction of the formula (2) tends to occur when the temperature of the trap section 510 is 300° C. or higher. In this embodiment, the target temperature of the trap section 510 is set to 500° C., which is higher than the first temperature (300° C.), so that the temperature of the trap section 510 will reach the first temperature or higher. Thus, the above-described reaction reliably occurs in the trap section 510. The first temperature, which is the possible lowest temperature of the trap section 510, may be 300° C. or higher, as described above. However, when the temperature of the substrate 100 when the process is performed in the chamber 20 becomes higher than 300° C., the first temperature is preferably further higher than this temperature. The reaction of the formula (2) tends to occur, in particular, when the temperature of the trap section 510 is further higher than the temperature at which the nickel carbonyl is generated in accordance with the formula (1).

In this manner, in the substrate processing apparatus 10 according to at least one embodiment, the trap section 510 is provided in the middle of the discharge pipe 50, which the structure enables decomposition of the nickel carbonyl and collection of the resultant nickel. Thus, it is possible to prevent the phenomenon of adhesion of some nickel carbonyl to the substrate 100 again.

The produced gas causes the reaction of the formula (2) upon passing through the trap section 510 and becomes a gas primarily containing carbon monoxide, which flows downstream. In this situation, if a downstream part of the discharge pipe 50, for example, the pipe 52 or the valve 530, has a temperature of 75° C. or higher, the reaction of the formula (1) can occur between the nickel contained in this part and the carbon monoxide contained in the gas as a result of the reaction of the formula (2), to yield nickel carbonyl again. As a result, toxic nickel carbonyl can be discharged to the outside through the pipe 54, or some nickel carbonyl can flow backward into the chamber 20 and adhere to the substrate 100 again.

In consideration of this, in the substrate processing apparatus 10 according to at least one embodiment, the buffer section 520 is provided downstream of the trap section 510, and the buffer section 520 is cooled by the cooling pipe 521. The buffer section 520 is cooled so that the temperature at its downstream end part will be the second temperature or lower, that is, 75° C. or lower, and accordingly, the temperature of a part downstream of the buffer section 520 of the discharge pipe 50 is also lowered to 75° C. or lower. This enables preventing occurrence of the reaction of the formula (1) at this part. Thus, at least parts of the pipe 52, the valve 530, the pipe 53, the pump 60, and the pipe 54 may use a material containing nickel, such as stainless steel.

The buffer section 520, which is provided adjacent to the trap section 510 that will have high temperature, may have a temperature of 75° C. or higher at some parts thereof. In one example, even when the cooling pipe 521 cools so that the temperature of the downstream end part of the buffer section 520 will be 60° C., the temperature of the upstream end part of the buffer section 520 becomes 500° C., which is approximately the same as the temperature of the trap section 510. From this point of view, as in the case of the supply pipe 30, at least an inner surface of the buffer section 520 that is to be brought into contact with the gas having passed through the trap section 510 is preferably coated with a nickel-free material. Alternatively, the entire buffer section 520 is preferably formed of a nickel-free material. Examples of such a material include SiO₂, SiC, Al, Al₂O₃, nylon, and glass.

As described above, the substrate processing apparatus 10 according to at least one embodiment includes the chamber 20, the supply pipe 30, the discharge pipe 50, the trap section 510, the heater 511 (heating unit), the buffer section 520, and the cooling pipe 521 (cooling unit). The chamber 20 houses the substrate 100. The supply pipe 30 supplies the processing gas that contains carbon monoxide, into the chamber 20. The discharge pipe 50 discharges the produced gas from the chamber 20. The produced gas is produced through the reaction between the nickel contained in the substrate 100 and the carbon monoxide contained in the processing gas. The trap section 510 is provided in the middle of the discharge pipe 50. The heater 511 heats the trap section 510 so that the temperature of the trap section 510 will be the first temperature or higher, which the first temperature is 300° C. or higher and is higher than the process temperature of the substrate 100. The buffer section 520 is provided downstream of the trap section 510 in the discharge pipe 50. The cooling pipe 521 cools the buffer section 520 so that the temperature at the downstream end part of the buffer section 520 will be the second temperature or lower, which the second temperature is lower than the first temperature. The second temperature is preferably set to 75° C. or lower.

The processing method of the substrate 100, which is executed by the substrate processing apparatus 10, includes: housing the substrate 100 in the chamber 20; supplying the processing gas that contains carbon monoxide, into the chamber 20; discharging the produced gas, which is generated through the reaction between the nickel contained in the substrate 100 and the carbon monoxide contained in the processing gas, from the chamber 20; and causing the produced gas that is discharged from the chamber 20, pass through the trap section 510 that has the first temperature which is 300° C. or higher and is higher than the process temperature of the substrate 100. The processing method also includes causing the gas that has passed through the trap section 510, pass through the buffer section 520 in which a part thereof, specifically, the downstream end part, has the second temperature lower than the first temperature.

The substrate processing apparatus 10 that processes the substrate 100 by using such a method enables decomposing the nickel carbonyl, which is generated in the chamber 20, in the trap section 510 and collecting the resultant nickel.

The nickel that is contained in the substrate 100 is collected in the state of nickel, instead of being collected in the state of toxic nickel carbonyl, and therefore, safety in maintenance operation is obtained. In addition, the nickel is mostly collected only at the trap section 510, which makes it easy to perform maintenance operation.

Moreover, in the substrate processing apparatus 10, the temperature of the part downstream of the buffer section 520 of the discharge pipe 50 becomes 75° C. or lower, whereby nickel carbonyl is not generated at this part. Thus, the amount of the nickel carbonyl in the gas that is discharged to the outside through the pipe 54, is reduced to a sufficiently low level.

Other components of the substrate processing apparatus 10 will be described. As shown in FIG. 2, the substrate processing apparatus 10 is provided with a cleaning pipe 40. The cleaning pipe 40 is configured to supply oxygen as a cleaning gas, into the chamber 20 at the time of maintenance of the substrate processing apparatus 10.

As in the case of the supply pipe 30, the cleaning pipe 40 enters the chamber 20 from a lower part of the side surface of the chamber 20 and extends upward in the chamber 20. The part that thus extends upward of the cleaning pipe 40 is housed in the protrusion part 21 of the chamber 20.

A part of the side surface facing the holder 200 of the cleaning pipe 40 is formed with multiple introducing ports 42. The introducing ports 42 are openings that serve as outlets of the oxygen having passed through the cleaning pipe 40. The multiple introducing ports 42 are mutually spaced in the vertical direction or are formed with intervals that are adjusted so that the flow of gas in the chamber 20 will be uniform.

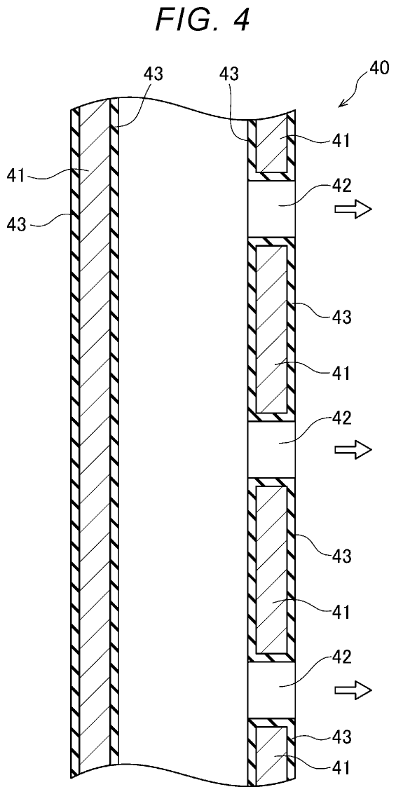

FIG. 4 shows a cross section obtained by cutting a part inside the chamber 20 of the cleaning pipe 40, at a plane passing a center axis along the longitudinal direction thereof. As shown in the drawing, the cleaning pipe 40 has a similar structure as the supply pipe 30 and includes a base material 41 and a coating layer 43. The base material 41 is a body part of the cleaning pipe 40 and is formed of a metal material, such as stainless steel.

The coating layer 43 covers the entire surface of the base material 41. The coating layer 43 is formed of a nickel-free material. Examples of such a material include SiO₂, SiC, Al, Al₂O₃, nylon, and glass. The coating layer 43 covers an outer surface and an inner surface of the base material 41 and the entire inner surface of the introducing port 42.

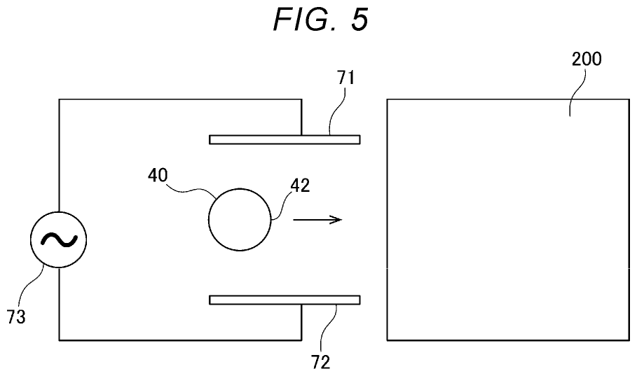

FIG. 5 schematically shows some components of the substrate processing apparatus 10 in a top view. As shown in the drawing, a pair of electrodes 71 and 72 face each other across the cleaning pipe 40, in the vicinity of the part extending upward of the cleaning pipe 40. The electrodes 71 and 72 are plate-shaped electrodes configured to generate an electric field around oxygen, which is supplied from the introducing ports 42 into the chamber 20, so as to convert the oxygen into oxygen radicals. The electrodes 71 and 72 are coupled to a power supply 73 for applying voltage therebetween. The power supply 73 uses an AC power supply, but may use a DC power supply. The power supply 73 is disposed outside the chamber 20, for example.

It is noted that the electrodes 71 and 72 are omitted in FIG. 2. The electrodes 71 and 72 are disposed at side positions across the cleaning pipe 40, along the depth direction of the paper surface in FIG. 2. The oxygen radicals maybe generated by another method, for example, a method using inductively coupled plasma.

At the time of maintenance of the substrate processing apparatus 10, oxygen is supplied from the introducing ports 42 of the cleaning pipe 40 into the chamber 20. Meanwhile, the electrodes 71 and 72 are applied with voltage by the power supply 73. Thus, the supplied oxygen is converted into oxygen radicals, and they reach each part in the chamber 20. It is noted that, although the holder 200 is shown in FIG. 5, the holder 200 may not be placed in the chamber 20 at the time of maintenance.

The nickel, which comes from the substrate 100 in processing the substrate 100, adheres to the inner surface of the chamber 20 and so on. When the oxygen radicals that are generated as described above reach the nickel, the nickel combines with the oxygen radicals to produce nickel oxides.

Thereafter, in a manner similar to that in processing the substrate 100, the chamber 20 is heated by the heater 300, and the processing gas that contains carbon monoxide is supplied from the introducing ports 32 of the supply pipe 30 into the chamber 20. The carbon monoxide combines with the nickel oxides to produce nickel carbonyl, and the produced nickel carbonyl is discharged from the chamber 20 through the discharge pipe 50. The nickel that adheres to the inner surface of the chamber 20 and so on is oxidized in advance by the oxygen radicals, whereby combining with carbon monoxide thereafter is more facilitated, resulting in efficient cleaning.

In processing the substrate 100, at the time of heating the substrate 100 by the heater 300, the cleaning pipe 40, as well as the supply pipe 30, is heated simultaneously to a temperature of 75° C. or higher. For this reason, in the case of forming the cleaning pipe 40 by using a material containing nickel, such as stainless steel, the reaction of the formula (1) occurs also on the surface of the cleaning pipe 40, and the produced nickel carbonyl can reach the substrate 100. As a result, the nickel carbonyl adheres to the substrate 100 to be decomposed, and the resultant nickel contaminates the substrate 100.

In view of this, in the substrate processing apparatus 10, the surface of the cleaning pipe 40, as well as the surface of the supply pipe 30, is covered with the coating layer 43 that is made of a nickel-free material. With this structure, the reaction of the formula (1) does not occur on the surface of the cleaning pipe 40, whereby the phenomenon of adhesion of the nickel carbonyl to the substrate 100 is prevented.

The area that is covered with the coating layer 43 of the cleaning pipe 40 may be the entire surface of the cleaning pipe 40 or may be only a part of the surface of the cleaning pipe 40. The “part of the surface of the cleaning pipe 40” is, for example, a part to be heated to 75° C. or higher and to be brought into contact with carbon monoxide of the cleaning pipe 40. Thus, for example, the part outside the outer wall 1 of the cleaning pipe 40 may not be covered with the coating layer 43. When the amount of carbon monoxide that enters the cleaning pipe 40 from the introducing ports 42 is a negligible degree, the inner surface of the cleaning pipe 40 may not be covered with the coating layer 43.

The base material 41 of the cleaning pipe 40 may be formed of a nickel-free material. Examples of such a material include SiO₂, SiC, Al, Al₂O₃, nylon, and glass. In this case, it is not necessary to form the coating layer 43, as shown in FIG. 4. In this manner, the cleaning pipe 40 may be, not partially, but entirely, formed of a nickel-free material.

When a structural component that may have a temperature of 75° C. or higher is disposed in the chamber 20, in addition to the supply pipe 30 and the cleaning pipe 40, this structural component is also preferably covered with a coating layer that is made of a nickel-free material. Alternatively, the entire structural component may be formed of a nickel-free material.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a chamber configured to house a substrate;
a supply pipe configured to supply a processing gas to the chamber;
a discharge pipe configured to discharge a gas produced in the chamber;
a trap section disposed in the discharge pipe;
a heater configured to heat the trap section so that a first temperature of the trap section is higher than a process temperature of the substrate and is 300° C. or higher;
a buffer section disposed downstream of the trap section in the discharge pipe; and
a cooler configured to cool the buffer section so that a second temperature at a downstream end part of the buffer section is lower than the first temperature.

2. The substrate processing apparatus according to claim 1, wherein the supply pipe is at least partially made of a nickel-free material.

3. The substrate processing apparatus according to claim 2, wherein the nickel-free material is at least one material selected from the group consisting of SiO₂, SiC, Al, Al₂O₃, nylon, and glass.

4. The substrate processing apparatus according to claim 1, wherein the supply pipe has (i) a base material and (ii) a coating layer that covers a surface of the base material and is made of a nickel-free material.

5. The substrate processing apparatus according to claim 4, wherein the base material of the supply pipe is made of a metal material containing nickel.

6. The substrate processing apparatus according to claim 1, wherein a part of the discharge pipe upstream of the trap section is made of a nickel-free material.

7. The substrate processing apparatus according to claim 6, wherein the part of the discharge pipe upstream of the trap section is made of quartz and is integrally formed with the chamber as one body.

8. The substrate processing apparatus according to claim 1, wherein at least an inner surface of the buffer section is made of a nickel-free material.

9. The substrate processing apparatus according to claim 8, wherein the nickel-free material is at least one material selected from the group consisting of SiO₂, SiC, Al, Al₂O₃, nylon, and glass.

10. The substrate processing apparatus according to claim 1, wherein a part of the discharge pipe downstream of the buffer section is made of a metal material containing nickel.

11. The substrate processing apparatus according to claim 2, further comprising a cleaning pipe configured to supply a cleaning gas into the chamber, the cleaning pipe being at least partially made of a nickel-free material.

12. The substrate processing apparatus according to claim 11, wherein the cleaning pipe has (i) a base material and (ii) a coating layer that covers a surface of the base material and is made of a nickel-free material.

13. The substrate processing apparatus according to claim 1, wherein the second temperature is 75° C. or lower.

14. A processing method of a substrate, comprising:
housing a substrate in a chamber, the substrate containing nickel;
supplying a processing gas containing carbon monoxide to the chamber;
discharging a produced gas from the chamber, the produced gas being produced by a reaction between the nickel contained in the substrate and the carbon monoxide contained in the processing gas; and
causing the produced gas, that has been discharged from the chamber, pass through a trap section having a first temperature that is higher than a temperature of the substrate and is 300° C. or higher.

15. The processing method of the substrate according to claim 14, further comprising causing a gas, that has passed through the trap section, pass through a buffer section in which a part of the buffer section is at a second temperature that is lower than the first temperature.

16. The processing method of the substrate according to claim 15, wherein the second temperature is 75° C. or lower.

17. The processing method of the substrate according to claim 14, wherein nickel carbonyl is produced as the produced gas by a reaction between the nickel and the carbon monoxide.

18. The processing method of the substrate according to claim 17, wherein the temperature of the substrate at the time of producing the nickel carbonyl is set to 75° C. or higher.

19. The processing method of the substrate according to claim 17, wherein the nickel carbonyl is made to pass through the trap section to be decomposed into nickel and carbon monoxide, and the resultant nickel is collected at the trap section.

20. The processing method of the substrate according to claim 14, further comprising:
supplying a cleaning gas that contains oxygen radicals, into the chamber; and
supplying carbon monoxide into the chamber and heating the chamber so that nickel adhering to an inside of the chamber reacts with the oxygen radicals and the carbon monoxide and is removed from the inside of the chamber.
